(19) United States
(12) Patent Application Publication
(10) Pub. No.: US 2002/0168834 A1
(43) Pub. Date: Nov. 14, 2002

(54) Method for fabricating shallow rench isolation structure

(76) Inventors: Chien-Wei Chen, Hsinchu (TW); Jiun-Ren Lai, Pingtung (TW); Chun-Lein Su, Shanhua Chen (TW)

Correspondence Address: J.C. Patents, Inc., Suite 250, 4 Venture, Irvine, CA, 92618, US

(21) Appl. No.: 10/104,967

(22) Filed: Mar. 22, 2002

(30) Foreign Application Priority Data
May 11, 2001 (TW) 90111228

(51) Int. Cl. H01L 21/76

(52) U.S. Cl. 438/427; 438/400; 438/424

(57) ABSTRACT

A method for fabricating shallow trench isolation structures. A substrate is provided on which are sequentially stacked a buffer oxide layer and a mask layer. A plurality of trenches with different densities is formed in the stack of substrate/buffer oxide/mask layers. An insulating layer is formed over the substrate to fill the trenches. A planarized sacrificial layer is formed by spin coating polymer on the insulating layer. The sacrificial layer is completely removed by dry etching. A predetermined thickness of the insulating layer is removed such that a preliminary planarization of the insulating layer is obtained. By adjusting the etching parameters, the insulating layer is continuously removed by dry etching until the mask layer is exposed. The mask layer and buffer oxide layer are sequentially removed to expose a plurality of isolation structures with rounded surfaces.

### CROSS-REFERENCE TO RELATED APPLICATION

This application claims the priority benefit of Taiwan application serial No. 90111228, filed May 11, 2001.

### BACKGROUND OF THE INVENTION

1. Field of the Invention

The invention relates to a method for fabricating a electrically insulating structure. More particularly, the invention relates to a method for fabricating shallow trench isolation structures.

2. Description of the Related Art

As the integration of semiconductor devices improves, the design increasingly emphasizes the fabrication of semiconductor devices with a reduced size. Because the present semiconductor processes attain a degree of miniaturization under 0.18 microns, a conventional local oxidation (LOCOS) can no longer be performed to form the electrically insulating layer (for example made of silicon oxide) in the memory device. The method of fabricating shallow trench isolation structures thus is one of the most commonly used methods to build up the electrically insulating structures. Within the process of fabricating shallow trench isolation structures, a high density plasma chemical vapor deposition (HDPCVD) is particularly performed to deposit and fill the trenches with a silicon oxide layer, because the high density plasma chemical vapor deposition (HDPCVD) allows for a good gap filling of the silicon oxide.

However, a drawback of the high density plasma chemical vapor deposition (HDPCVD) is that the material layer formed thereby has a poor conformity. As a result, a chemical mechanical polishing is usually necessary to planarize the silicon oxide that fills the trenches until an adequate thickness is obtained. However, because the trenches are usually distributed with different densities in the same substrate, the removal of the silicon oxide during the chemical mechanical polishing thus is faster in regions of higher density of pattern trenches. A dishing effect thus generated in regions of higher density of pattern trenches directly causes a negative impact on the uniformity of the device.

To solve the above problem, the U.S. Pat. No. 5,998,279 issued to Liaw discloses a method for forming shallow trench isolation structures using a reverse mask. The method disclosed by the U.S. Pat. No. 5,998,279 comprises first forming a silicon oxide by a high density plasma chemical vapor deposition (HDPCVD) to fill a plurality of trenches formed with different densities in a patterned stack of substrate/buffer oxide/silicon nitride layers. Then, a photoresist layer is formed on the silicon oxide. A photolithography process is performed to define the photoresist layer covering the regions of higher density of pattern trenches while a reverse mask is formed over the trenches of the regions with lower pattern trench densities. Then, with the use of the photoresist and the reverse mask as masks, the silicon oxide is etched until an adequate thickness is obtained. Then, the photoresist and reverse mask are removed to reverse the regions of low density into regions of high density, and a chemical mechanical polishing is performed to remove the silicon oxide until the underlying silicon nitride is exposed. Then, the silicon nitride layer and buffer oxide layer are removed to form the shallow trench isolation structures.

The above-described method has at least the following drawbacks. Additional steps, such as the photolithography process to form the reverse mask, the partial removal of the silicon oxide through the reverse mask, and the removal of the photoresist and reverse mask, are necessary. As a result, the whole process for fabricating the shallow trench isolation structures is disadvantageously complicated, while the manufacturing cost is also increased. Besides, with respect to the small size of the active regions, the exposure step during the photolithography process is constrained to a so called critical layer, which therefore significantly limits the photolithography process. As a result, the additional photolithography process negatively increases the difficulty of the fabrication of shallow trench isolation structure.

Moreover, after the reverse mask layer is removed, a strict control of the chemical mechanical polishing performed on the silicon oxide is still necessary to avoid a dishing effect and non-uniformity problem.

### SUMMARY OF THE INVENTION

An aspect of the present invention is to provide a method for fabricating shallow trench isolation structures that can allow for an effective reduction of the dishing effect caused by differences of the density of the pattern trenches.

Another aspect of the present invention is to provide a method for fabricating shallow trench isolation structures that does not need photolithography, etching and photoresist removal processes such that the manufacturing cost and difficulty of the process can be reduced.

Further, another aspect of the present invention is to provide a method for fabricating shallow trench isolation structures in which a dry etching is performed instead of the chemical mechanical polishing conventionally performed.

To attain the foregoing and other aspects, the present invention, according to a preferred embodiment, provides a method for fabricating shallow trench isolation structures that comprises the following steps. A substrate is provided on which are sequentially stacked a buffer oxide layer and a mask layer. A plurality of trenches with different densities are formed in the stack of substrate/buffer oxide/mask layers. An insulating layer is formed over the substrate to fill the trenches. By spin on coating, a planarized sacrificial layer made of polymer is formed on the insulating layer. The sacrificial layer is completely removed by dry etching. A predetermined thickness of the insulating layer is removed such that a preliminary planarization of the insulating layer is obtained. By adjusting the etching parameters, the insulating layer is removed by dry etching until the mask layer is exposed. Finally, the mask layer and buffer oxide layer are sequentially removed to expose a plurality of isolation structures with rounded surfaces.

In accordance with the above-described embodiment of the present invention, an advantage of the present invention is the formation of a planarized spin on polymer on the insulating layer. A dry etching within a same etching reaction chamber is then continuously performed by means of an adequate adjustment of the composition and ratio of etching gases to obtain the desired etching selectivity until the isolation structures are formed. Compared to the conventional method, the present invention thus advantageously does not require the traditional sequence of photolithography, etching, and photoresist removal processes. As a result, the manufacturing is simplified while its cost is reduced.

Because the present invention does not require the traditionally performed photolithography process, the present invention thus can overcome the dimensional limitations of the exposure during the photolithography process. The shallow trench isolation structures thus can be efficiently fabricated by the present invention even when the size of the devices is reduced.

Moreover, since the isolation structures of the present invention are fabricated with rounded surfaces, which differs from the conventional right-angle-shaped isolation structures obtained by chemical mechanical polishing, the subsequent semiconductor processes advantageously can be more easily controlled.

Furthermore, since, in the present invention, dry etching is substituted for the conventionally performed chemical mechanical polishing, dishing and nonuniformity issues related to the chemical mechanical polishing thus can be advantageously overcome.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A is a cross-sectional view of a substrate at an intermediary starting stage in a method for fabricating shallow trench isolation structures according to a preferred embodiment of the present invention;

FIG. 1B is a cross-sectional view of a substrate at an intermediary stage in the method of the present invention when the trenches are filled, according to a preferred embodiment of the present invention;

FIG. 1C is a cross-sectional view of a substrate at an intermediary stage of the method of the present invention when a planarized spin on polymer is formed over the substrate, according to a preferred embodiment of the present invention; and

FIG. 1D through FIG. 1G are cross-sectional views of a substrate at various stages in the method of the present invention when a dry etching is performed to form the isolation structures, according to a preferred embodiment of the present invention.

### DESCRIPTION OF THE PREFERRED EMBODIMENTS

The following detailed description of the embodiments and examples of the present invention with reference to the accompanying drawings is only illustrative and not limiting.

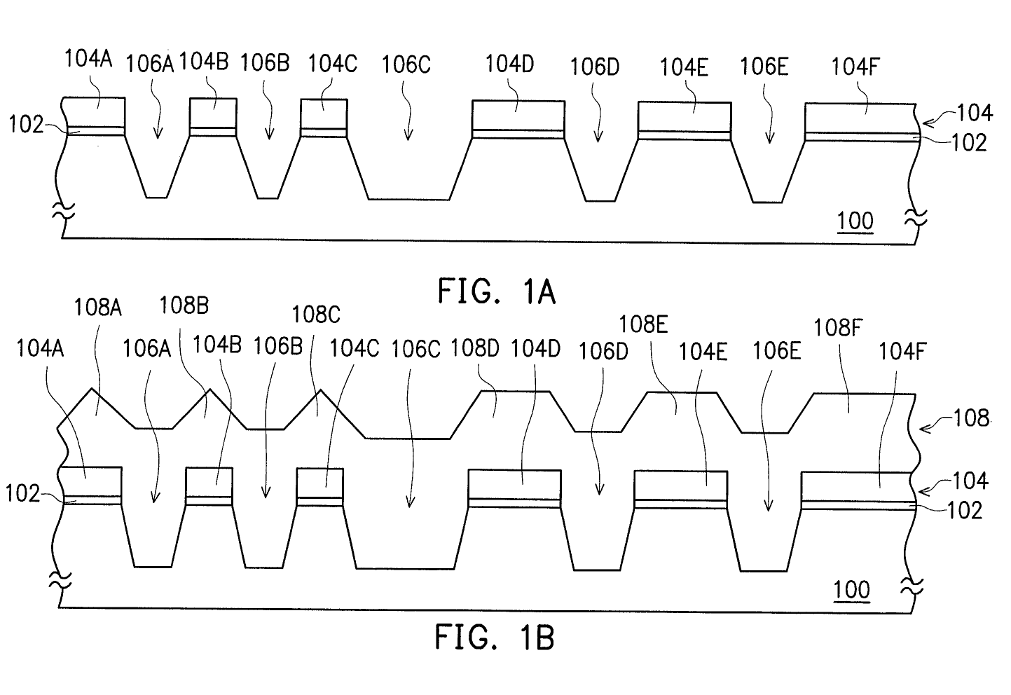

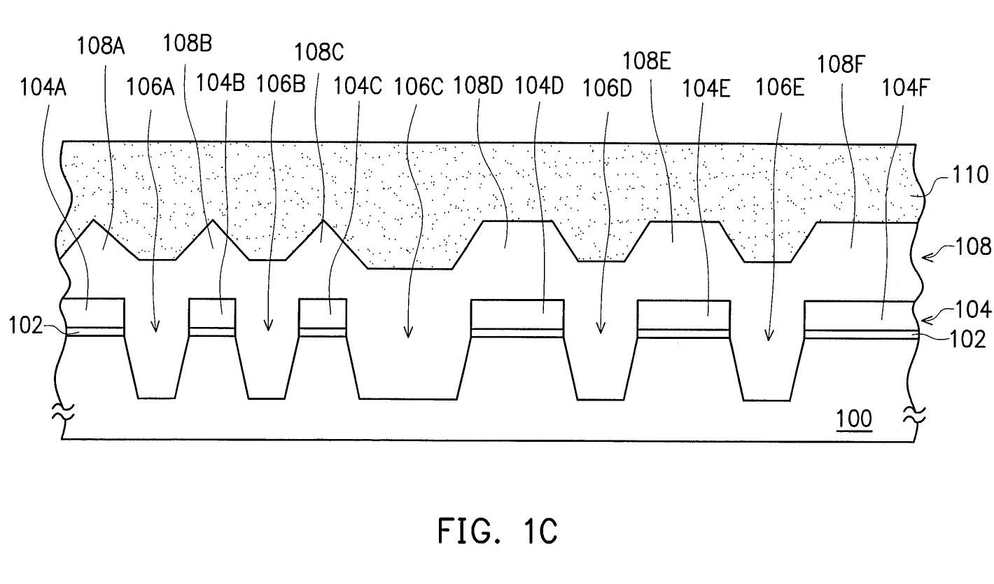

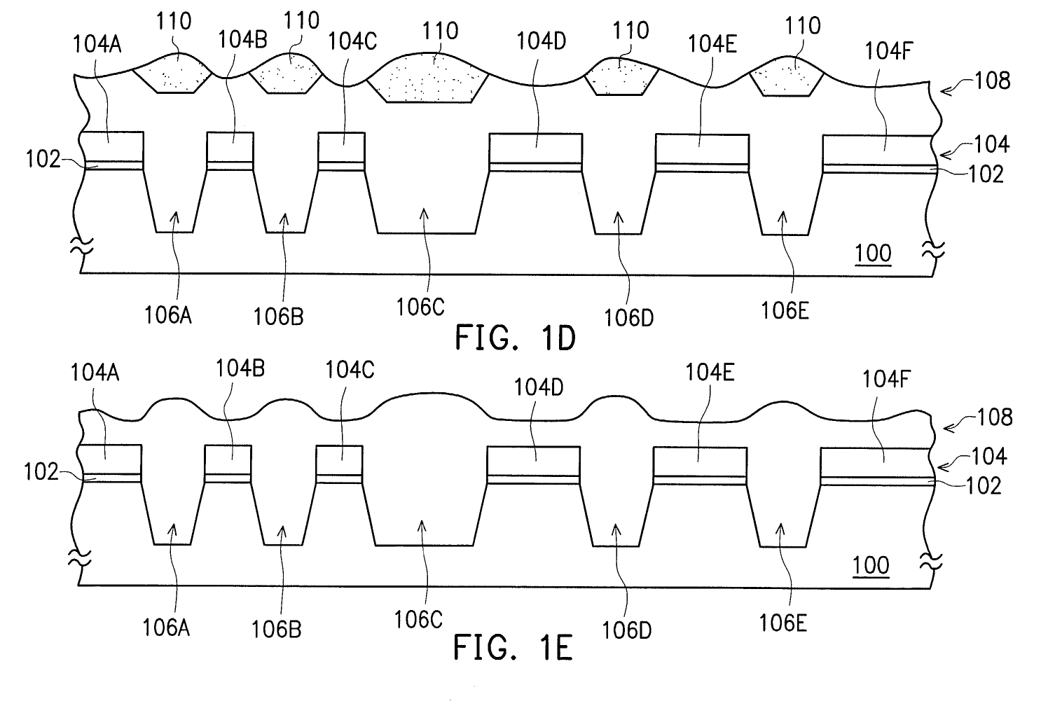

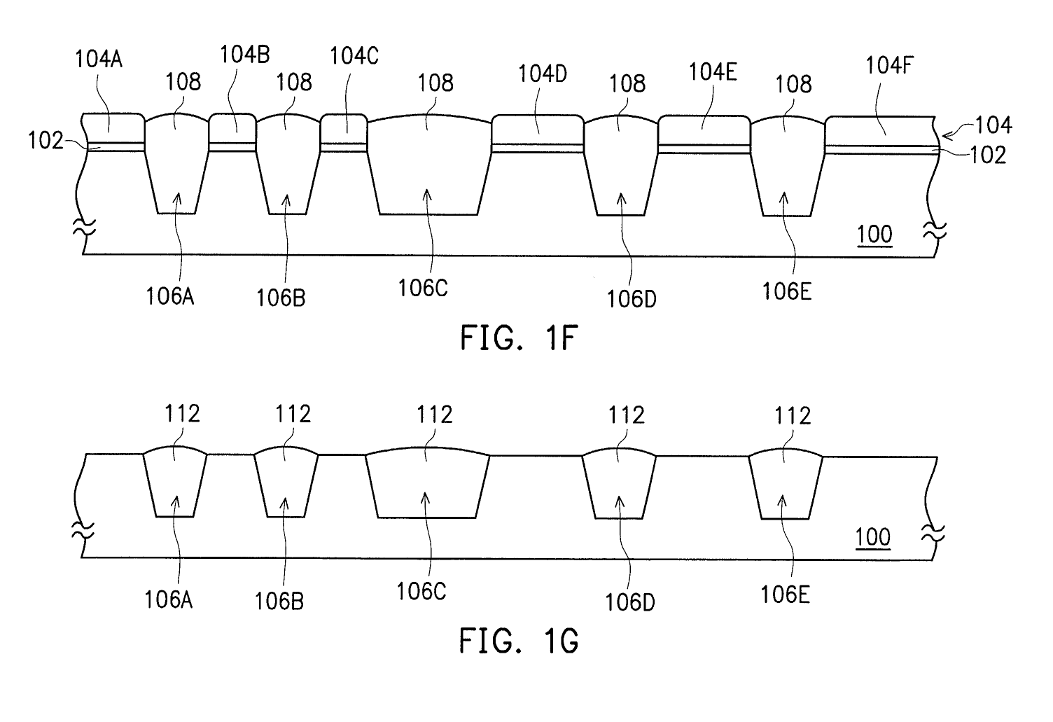

Referring now to FIG. 1A through FIG. 1G, various cross-sectional views schematically illustrate various stages in a method for fabricating a shallow trench isolation structure according to a preferred embodiment of the present invention.

With reference to FIG. 1A, a buffer oxide layer 102 and a mask layer 104 are respectively formed on a substrate 100. Then, the mask layer 104, buffer oxide layer 102 and substrate 100 are partially removed to form a plurality of trenches 106A through 106E. The mask layer 104 is made of, for example, nitride oxide. The mask layer 104, buffer oxide layer 102 and substrate 100 are patterned in such a manner that the formed pattern trenches 106A through 106E are not formed with a uniform density. In FIG. 1A, the patterns 104A through 104C are distributed with a density higher than that with which the patterns 104D through 104F are distributed over the substrate 100.

Next with reference to FIG. 1B, an insulating layer 108 is formed over the substrate 100 to fill the trenches 106A through 106E. The insulating layer 108 can be formed by, for example, a high density plasma chemical vapor deposition (HDPCVD) of silicon oxide. In the present embodiment, the thickness of the formed insulating layer 108 is, for example, approximately 8000 angstroms. Because of a specific propriety of the high density plasma chemical vapor deposition (HDPCVD), the formed insulating layer 108 is not conformal and comprises protrusions 108A through 108F.

Next with reference to FIG. 1C, a sacrificial layer 110 is formed over the substrate 100. The sacrificial layer 110 can be, for example, a spin on polymer (SOP), such as that sold under the trademark ACCUFLO®, formed by spin coating. In the present embodiment of the present invention, the exemplary sacrificial layer 110 is approximately 4000 angstroms to 6000 angstroms thick. Because the sacrificial layer 110 is formed by spin coating and made of a material on which a planarization process can be performed, a planarized surface thus can be obtained over the substrate.

Next with reference to FIG. 1D through 1E, a back etching then is performed to completely remove the sacrificial layer 110 and partially remove a predetermined thickness of the insulating layer 108 such that a relatively planarized insulating layer 108 is obtained. In the present invention, the exemplary back etching is a dry etching using CHF₃, CF₄, oxygen, and nitrogen gases under a pressure of approximately 200 mTorrs to 400 mTorrs. The power of the dry etching is approximately 800 watts to 1400 watts. In the present embodiment, the CHF₃/CF₄ ratio is approximately 1/9, the oxygen/nitrogen ratio is approximately 1/1, and the gas flow of nitrogen approximately 10 sccms to 40 sccms. With the foregoing exemplary conditions of deposition, the etching selectivity of the insulating layer with respect to the sacrificial layer is between approximately 2 and 5. After etching, the remaining insulating layer 108 is approximately 4000 angstroms to 6000 angstroms.

By adjusting the etching parameters of the above back etching to set an adequate etching selectivity, the etching of the insulating layer 108 is faster than that of the sacrificial layer 110. As a result, at an intermediary stage of the back etching as shown in FIG. 1D, a portion of the sacrificial layer 110 remains on the insulating layer 108 at the locations over the trenches 106A through 106E while the surface of the insulating layer 108 locally there around is lower.

Next with reference to FIG. 1E, a cross-sectional view schematically illustrates the substrate after the sacrificial layer 110 has been completely removed by the above back etching. The protrusions 108A through 108F of the insulating layer 108 and the complete sacrificial layer have been removed by the back etching such that the surface over the substrate is relatively more planarized. The surface of the insulating layer 108 locally over the locations of the trenches 106A through 106E is higher than the surface of the insulating layer 108 at the locations around each of the trenches 106A through 106E.

Next with reference to FIG. 1F, the insulating layer 108 then is also back-etched until the surface of the mask layer 104 is exposed. The exemplary back etching is a dry back-etching using CHF₃, CF₄, and argon gases under a pressure of approximately 80 mTorrs to 200 mTorrs, and with a power between approximately 400 watts and 1000 watts. The exemplary CHF₃/CF₄ gas ratio is about 7/1 while the gas flow of argon is approximately 50 sccms to 200 sccms. With the above etching conditions, the etching selectivity of the insulating layer with respect to the mask layer is between approximately 1 and 12.

Thus, the above-described etching of the insulating layer 108, through adequate adjustment of the composition of gases, the gas pressure, the power, and the CHF₃/CF₄ gas ratio, is a dry etching similar to that of the sacrificial layer 110. The shallow trench isolation structures thus can be completed via a single dry back etching in the same etching reaction chamber. As a result, compared to the conventional method that uses a reverse mask, the present invention is simpler. Moreover, the single dry etching is advantageously substituted for a chemical mechanical polishing that was conventionally performed. As a result, the manufacturing cost can be reduced.

With reference to FIG. 1G, the mask layer 104 and buffer oxide layer 102 then are respectively removed to form a plurality of isolation structures 1 12 with rounded surfaces in the substrate. The mask layer 104 is removed by, for example, a wet etching using a thermal phosphoric acid. The buffer oxide layer 102 is removed by, for example, a wet etching using a fluoride acid. In the present invention, the dry and wet etchings, subsequently performed to respectively remove the insulating layer 108 and mask layer 104 and buffer oxide layer 102, allows for a shape of the surface of the isolation structures that is rounded. In contrast, the conventional isolation structures, achieved by a chemical mechanical polishing, are substantially right-angle-shaped. The isolation structures 112 with rounded surfaces obtained by the present invention thus allow for an easier control of the processes, such as etchings, that are subsequently performed.

In conclusion, a major aspect of the present invention is the formation of a planarized spin-on-polymer layer on the silicon oxide layer, and dry etching the both to form a plurality of isolation structures by subsequently adjusting the conditions of the etching to generate adequate etching selectivity. Because the advantageous single dry etching is performed in the same etching reaction chamber by only adjusting the etching parameters, the conventional sequence of photolithography, etching, and photoresist removal processes no longer is necessary. The manufacturing process thus is advantageously simplified while its cost is reduced. Because the present invention does not require the conventional formation of a reverse photoresist, the problems related to the limitations of the conventional photolithography process when the size of the devices is reduced also can be advantageously overcome by the present invention. Moreover, because the isolation structures of the present invention, formed by a dry etching, comprise round-shaped surface, control of the subsequent processes, such as etching, is facilitated. Inasmuch as the cost of the dry etching is lower than that of the replaced chemical mechanical polishing, the manufacturing cost of the fabrication of isolation structures consequently can be lowered while the conventional dishing issue related to the chemical mechanical polishing can be overcome.

It will be apparent to those skilled in the art that various modifications and variations can be made to the structure of the present invention without departing from the scope or spirit of the invention.

What is claimed is:

1. A method for fabricating shallow trench isolation structures, comprising:
providing a substrate;
forming a buffer oxide on the substrate;
forming a mask layer on the buffer oxide;
forming a plurality of trenches in the substrate;
forming an insulating layer made of silicon oxide over the substrate to fill the trenches;
forming a sacrificial layer on the insulating layer;
performing a first back etching to sequentially remove the sacrificial layer and a predetermined thickness of the insulating layer such that the insulating layer is relatively planarized, wherein an etching rate of the sacrificial layer is lower than that of the insulating layer;
performing a second back etching to remove the insulating layer until the mask layer is exposed;
removing the mask layer; and
removing the buffer oxide layer to form a plurality of shallow trench isolation structures with rounded surfaces.

2. The method of claim 1, wherein the insulating layer is formed by a high density plasma chemical vapor deposition.

3. The method of claim 1, wherein the sacrificial layer is formed by a spin-on coating.

4. The method of claim 3, wherein the sacrificial layer is made of a spin-on polymer.

5. The method of claim 1, wherein a thickness of the sacrificial layer is about 4000 angstroms to 6000 angstroms.

6. The method of claim 1, wherein the first and second etchings are subsequently performed in a same etching reaction chamber.

7. The method of claim 1, wherein the first back etching is a dry back etching using CHF₃, CF₄, nitrogen, and oxygen gases under a pressure of about 200 mTorrs to 400 mTorrs, and with a power of about 800 watts to 1400 watts.

8. The method of claim 7, wherein the CHF3/CF4 gas ratio of the dry etching is about 1/9.

9. The method of claim 7, wherein an oxygen/nitrogen gas ratio is about 1/1.

10. The method of claim 7, wherein a gas flow of the nitrogen is about 10 sccms to 40 sccms.

11. The method of claim 1, wherein the second back etching is a dry back etching using CHF₃, CF₄, and argon gases under a pressure of about 80 mTorrs to 200 mTorrs, and with a power of about 400 watts to 1000 watts.

12. The method of claim 11, wherein a CHF₃/CF₄ gas ratio of the second back etching is about 7/1.

13. The method of claim 11, wherein a gas flow of the argon is about 50 sccms to 200 sccms.

14. A method of fabricating shallow trench isolation structures, comprising:
providing a substrate with a buffer oxide layer and a mask layer sequentially arranged on the substrate, a stack of the substrate, buffer oxide layer, and mask layer having a plurality of trenches formed therein;
forming an insulating layer made of silicon oxide over the substrate to fill the trenches;
forming a sacrificial layer with a planarized surface on the insulating layer;
performing a back etching to remove the complete sacrificial layer and the insulating layer until the mask layer is exposed, an etching rate of the insulating layer being faster than that of the sacrificial layer;
removing the mask layer; and
removing the buffer oxide layer to form a plurality of shallow trench isolation structures with rounded surfaces.

15. The method of claim 14, wherein the insulating layer is formed by a high density plasma chemical vapor deposition.

16. The method of claim 14, wherein the sacrificial layer is formed by a spin-on coating.

17. The method of claim 16, wherein the sacrificial layer is made of a spin-on polymer.

18. The method of claim 14, wherein the back etching further comprises:
performing a first etching to remove completely the sacrificial layer and a predetermined thickness of the insulating layer such that a preliminary planarization of the insulating layer is achieved; and
performing a second etching to remove the insulating layer until the mask layer is exposed.

19. The method of claim 18, wherein the first and second etchings are performed in a same etching reaction chamber.

20. The method of claim 18, wherein the first etching is a dry etching performed under a plurality of conditions comprising:
a gas pressure of about 200 mTorrs to 400 mTorrs;
a power of about 800 watts to 1400 watts; and
a gas source comprising CHF₃, CF₄, nitrogen, and oxygen gases, a CHF₃/CF₄ gas ratio being about 1/9 and a oxygen/nitrogen gas ratio being 1/1 while a nitrogen gas flow is about 10 sccms to 40 sccms.

21. The method of claim 18, wherein the second etching is a dry etching performed under a plurality of conditions comprising:
a gas pressure of about 80 mTorrs to 200 mTorrs;
a power of about 400 watts to 1000 watts; and
a gas source comprising CHF₃, CF₄, and argon gases, a CHF₃/CF₄ gas ratio being about 7/1 while an argon gas flow is about 50 sccms to 200 sccms.
